(19) United States
(12) Patent Application Publication
(10) Pub. No.: US 2014/0340076 A1
(43) Pub. Date: Nov. 20, 2014

(54) Sensor unit

(71) Applicant: VEGA Grishaber KG, Wolfach (DE)

(72) Inventor: Thomas ILG, Hausach (DE)

(73) Assignee: VEGA Grishaber KG, Wolfach (DE)

(21) Appl. No.: 14/253,987

(22) Filed: Apr. 16, 2014

(30) Foreign Application Priority Data
Apr. 26, 2013 (EP) 13 165541.7

(51) Int. Cl. G01R 1/04

(52) U.S. Cl. CPC G01R 1/04
USPC 324/156

(57) ABSTRACT

A sensor unit comprising a sensor, a sensor electronic connected to the sensor, and a first connection unit, which is connected to the sensor electronic, with the sensor, the sensor electronic, and the first connection unit being arranged in a tubular housing, and with the first connection electronic being able to contact a second connection unit embodied in a corresponding fashion, with a formed part with an internal contour being arranged in the housing in a torque-proof fashion, with the internal contour and an external contour of the first connection unit and/or the second connection unit being embodied at least sectionally corresponding to each other, and the internal contour comprising at least one fastening section, which is embodied such that any distortion of the first and/or second connection unit is prevented in reference to the formed part.

### STATEMENT REGARDING FEDERALLY SPONSORED RESEARCH OR DEVELOPMENT

No federal government funds were used in researching or developing this invention.

### CROSS REFERENCE TO RELATED APPLICATIONS

This patent application claims priority European Patent Application 13 165541.7, filed on Apr. 26, 2013.

### NAMES OF PARTIES TO A JOINT RESEARCH AGREEMENT

Not applicable.

### SEQUENCE LISTING INCLUDED AND INCORPORATED BY REFERENCE HEREIN

Not applicable.

### BACKGROUND

1. Field of the Invention

The invention relates to a sensor unit.

2. Background of the Invention

The current state of knowledge is as follows.

Various sensor units are known from prior art, comprising a sensor, a sensor electronic connected to the sensor, and a first connection unit, which is connected to the sensor electronic, with the sensor, the sensor electronic, and the first connection unit being arranged in a tubular housing and with the first connection unit can be in contact with a second connection unit, embodied correspondingly. Here, via a cable connection, the second connection unit usually establishes a connection to the control station and/or an evaluation electronic. In such cases, in which via the connection units not only a plug-in connection needs to be established but also a mechanically stable connection and perhaps one, which is protected from any circumventing process, it is common that the second connection unit is screwed into the tubular housing, for example via a cap nut.

When tightening the screw connection of the second connection unit in the tubular housing, during the screwing process, for example via the above-mentioned cap nut, torque acting in the circumferential direction can be transferred from the cap nut to the second connection unit, and via this (part) to the first connection unit and thus to the components connected to said connection unit, i.e. the sensor electronic as well as the sensor connected thereto. Such torque may lead to false measurements, particularly when it is transferred to the area of the sensor.

Furthermore, such torque may have negative effects upon the connection between the first connection unit and the sensor electronic and/or the connection between the sensor electronic and the sensor, each of which leading for example to a malfunction of the sensor unit when the connection is interrupted.

In order to avoid the above-mentioned faulty measurements and sensor malfunctions, a processing of the housing is suggested in prior art such that it is provided with one or more fastening areas, for example by way of cutting. For this purpose, the second connection unit is provided correspondingly with fastening areas, so that any torque, developing during the fastening of the second connection unit in the housing, is directly transferred via the fastening areas to said housing. This way, any forwarding of the introduced torque to the first connection unit, the sensor electronic, as well as the sensor can be avoided.

It is considered disadvantageous in the above-described process that here expensive processing of each individual housing is required for inserting the appropriate fastening areas.

In the embodiment known from prior art, in which the torque is transferred from the plug directly to the housing, a defined alignment of the socket in reference to these fastening areas mandatorily results by the fastening areas provided in the housing. Such an alignment is comparatively expensive and, when executed with insufficient precision, leads to a clamping effect between the plug and the socket when the plug is inserted into the housing.

The objective of the present invention is to provide a sensor unit, which avoids the disadvantages known from prior art.

This objective is attained in a sensor unit with the features as claimed herein.

### BRIEF SUMMARY OF THE INVENTION

In a preferred embodiment, a sensor unit comprising a sensor, a sensor electronic connected to the sensor, and a first connection unit, which is connected to the sensor electronic, with the sensor, the sensor electronic, and the first connection unit being arranged in a tubular housing, and with the second connection unit being able to contact a correspondingly embodied second connection unit, wherein a formed part with an internal contour is arranged in a torque-proof fashion in the housing, with the internal contour and an external contour of the first connection unit and/or the second connection unit being embodied sectionally in a mutually corresponding fashion, and the internal contour comprising at least one fastening section, which is embodied such that any distortion of the first and/or the second connection unit in reference to the formed part is prevented.

In another preferred embodiment, the sensor unit as described, wherein the formed part is provided with an internal contour with at least two, preferably 4 or 6 fastening areas.

In another preferred embodiment, the sensor unit as described, wherein the formed part is embodied with fastening areas arranged in pairs opposite each other and extending parallel.

In another preferred embodiment, the sensor unit as described, wherein the formed part is embodied with a rectangle, regular hexagon, or a regular polygon as the internal contour.

In another preferred embodiment, the sensor unit as described, wherein the internal contour comprises at least one recess pointing outwardly and the external contour at least one projection engaging the recess.

In another preferred embodiment, the sensor unit as described, wherein the internal contour is embodied stellar.

In another preferred embodiment, the sensor unit as described, wherein the formed part is impressed, adhered, welded, or soldered in the housing.

In another preferred embodiment, the sensor unit as described, wherein the formed part is made from plastic, preferably in an injection molding process.

In another preferred embodiment, the sensor unit as described, wherein the formed part is made from metal, preferably aluminum and preferably via a die casting process or from steel and preferably via a metal injection molding process.

In another preferred embodiment, the sensor unit as described, wherein the formed part is produced via a metal injection molding process.

In another preferred embodiment, the sensor unit as described, wherein the formed part is produced via a cutting process.

In another preferred embodiment, the sensor unit as described, wherein the connection units establish an electric connection and the first connection unit is embodied as a socket and the second connection unit as a plug.

In another preferred embodiment, the sensor unit as described, wherein the socket comprises latching elements, which undercut the formed part in a latching fashion for an axial fixation.

In another preferred embodiment, the sensor unit as described, wherein the plug undercuts the socket and can be fastened via a cap nut at the housing.

In another preferred embodiment, the sensor unit as described, wherein the internal contour is embodied such that an unambiguous assembly position of the connection unit is determined in reference to the formed part.

### BRIEF DESCRIPTION OF THE DRAWINGS

FIG. 1 is a line drawing evidencing a longitudinal cross-section through an exemplary embodiment of a sensor unit according to the invention,

FIG. 2 is a line drawing evidencing a perspective illustration of the plug of FIG. 1.

FIG. 3 is a line drawing evidencing the housing of FIG. 6 in a perspective view diagonally from the rear.

FIGS. 4a to 4d are line drawings evidencing various exemplary embodiments of a formed part.

### DETAILED DESCRIPTION OF THE INVENTION

A sensor unit according to the invention comprising a sensor, a sensor electronic connected to the sensor, and a first connection unit, which is connected to the sensor electronic, with the sensor, the sensor electronic, and the first connection unit being arranged in a tubular housing, and with the first connection unit can be in contact with a second connection unit, embodied correspondingly, is characterized in that a formed part, showing an internal contour of the formed part, is arranged in a torque-proof fashion in the housing, with the internal contour and the external contour of the first connection unit and/or the second connection unit at least sectionally being embodied in a mutually corresponding fashion and the internal contour showing at least one fastening area, which is embodied such that any distortion of the first and/or the second connection unit in reference to the formed part is prevented.

This way, according to the invention, the sensor unit known from prior art is further developed such that any transmission of torque cannot occur directly from the second connection unit, for example a plug, to the housing, but that a separate formed part is provided, which serves for transferring the torque to the housing.

By a torque-proof arrangement of the separate formed part inside the housing, here preferably a friction-fitting connection is generated, for example by the formed part being impressed in the housing, and any expensive processing of the housing can be omitted, with simultaneously a reliable compensation of the inserted torque being ensured by the housing. An appropriate torque, which for example is inserted into the arrangement by tightening a cap nut, can either be directly transferred via the second connection unit to the formed part and thus to the housing, or by a corresponding embodiment of the internal contour of the formed part to an external contour of the first connection unit.

In each of the above-mentioned cases any dispersal of the introduced torque upon the sensor electronic and the sensor connected to said sensor electronic can be reliably avoided, so that both any torque-induced faulty measurements as well as any torque-induced mechanic problems are reliably prevented.

In order to yield a reliable compensation of the introduced torque, here preferably several fastening areas may be provided at the internal contour of the formed part. Preferably, the formed part may be embodied with at least two, preferably four or six fastening areas.

When the formed part is embodied with paired fastening areas, arranged opposite each other and extending parallel, for example by forming the internal contour as a rectangle, a regular hexagon, or a regular octagon, internal contours can be generated which are easy in their production and simultaneously allow a variation of the position of installation of the connection unit connected to the formed part in reference to said formed part.

In another embodiment the internal contour is provided with at least one recess, pointing outwardly, and the external contour with at least one projection, pointing inwardly and engaging the recess, with in this exemplary embodiment at least one fastening area being formed. By providing a single such recess and a single such corresponding projection here an unambiguous position of installation of the connection unit can be determined in reference to the formed part.

By providing a plurality of recesses pointing outwardly at the formed part here an internal contour can be generated, which is for example embodied stellar. A stellar embodied internal contour allows then in turn a variation of the position of installation of the connection unit, which is connected to the formed part, in reference thereto such that increased flexibility is provided during the installation.

In a preferred embodiment of the sensor unit, the formed part is impressed, adhered, welded (e.g., by laser welding), or soldered (e.g., by brazing) in the housing.

By impressing, adhering, welding, or soldering a formed part in the housing here a quick and cost-effective assembly is yielded, which ensures a reliable transfer of torque from the formed part to the housing.

Due to the fact that the formed part is arranged inside the housing of the sensor unit an option is given to produce the formed part from plastic, for example.

A particularly simple embodiment provides that the formed part is made from plastic and produced in an injection molding process, resulting in an extremely cost-effective variant being generated, here.

In an alternative embodiment the formed part is made from metal, and preferably produced in a die casting process. Due to the fact that the formed part is not exposed to the process environment impacting the housing it may be made from aluminum, for example.

In a preferred embodiment the connection units establish an electric connection, with the first connection unit being embodied as a socket and the second connection unit as a plug.

In a preferred embodiment the first connection unit, embodied as a socket, is connected to the formed part, with the socket preferably showing latching elements, which undercut in a latching fashion the formed part for an axial fixation of the socket at the formed part.

(In) a preferred embodiment, in which the above-described torque develops, the plug is embodied such that it engages the socket and can be fastened via a cap nut at the housing.

By a point-symmetrical embodiment of the internal contour of the formed part additionally an unambiguous position of installation of the connection unit can be achieved in reference to the formed part.

### DETAILED DESCRIPTION OF THE FIGURES

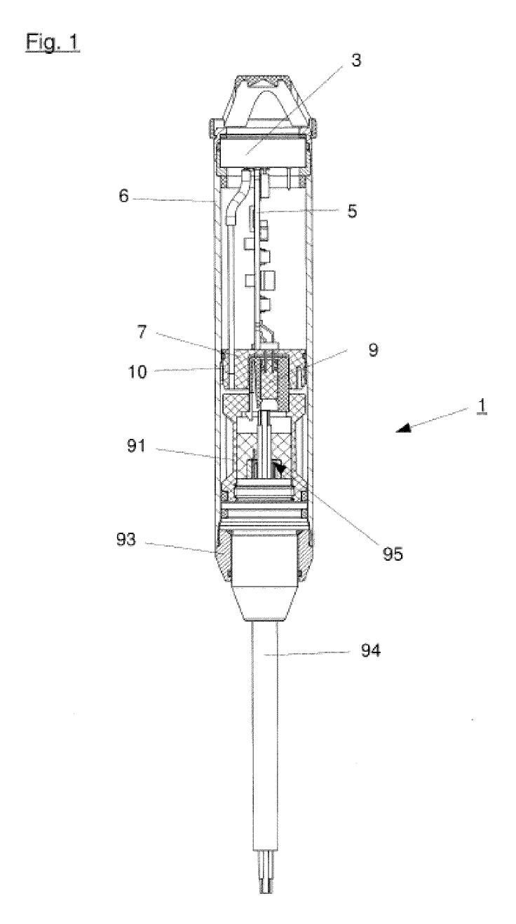

FIG. 1 shows a longitudinal cross-section through a sensor unit 1, in which the present invention can be implemented.

The sensor unit 1 comprises an essentially tubular embodied housing 6, in which at the front a sensor 3 is arranged, for example a ceramic manometer. The sensor 3 is connected to a sensor electronic 5, arranged inside the housing 6 and serving to evaluate and process measurements yielded. At the rear of the sensor electronic 5, e.g., at an end of the sensor electronic 5 facing away from the sensor 3, a first connection unit 7 is arranged, embodied as a socket. The socket 7 serves for the electric and mechanic contacting of the sensor electronic 5, with the processed measurements being provided via a plurality of connection pins. Additionally, starting the operation and controlling the configuration of the sensor unit 1 is possible via the socket 7.

At its rear the first socket 7 is in contact with a second connection unit 9, which in the present exemplary embodiment is embodied as a plug. The plug 9 is embodied with a plug housing 91, from which at the rear a connection cable 94 exits, supported via a strain relief 95 inside the plug housing 91. The plug 9 is fastened at the housing 6 of the sensor unit 1 via a cap nut 93, which for example may be provided with an O-ring 96 to seal the housing 6. Both the housing 6 as well as at least the sections of the plug housing 91 connected to a process environment are preferably made from an inert material, rather unsusceptible to corrosion, such as stainless steel or titanium.

In order to prevent the transmission of torque, which (develops) during the fastening of the plug 9 in the housing 6 of the sensor electronic 1 by the cap nut 93 upon the sensor electronic 5 and the sensor 3, the socket 7 is supported via a formed part 10, which is arranged in a torque-proof fashion in the housing 6. For supporting the socket 7, the formed part 10 comprises fastening sections, arranged radially opposite and extending parallel, which prevent any distortion of the socket 7 in reference to the formed part 10. Due to the fact that the formed part 10 is supported torque-proof in the housing 6 by way of impression, any torque generated by the cap nut 93 being tightened is transferred via the plug 9 to the socket 7 and therefrom via the formed part 10 to the housing 6, and thus any dispersal of the torque upon the sensor electronic 5 and the sensor 3 is prevented.

The torque-proof arrangement of the formed part 10 in the housing 6 occurs, for example, by impressing or adhering the formed part 10.

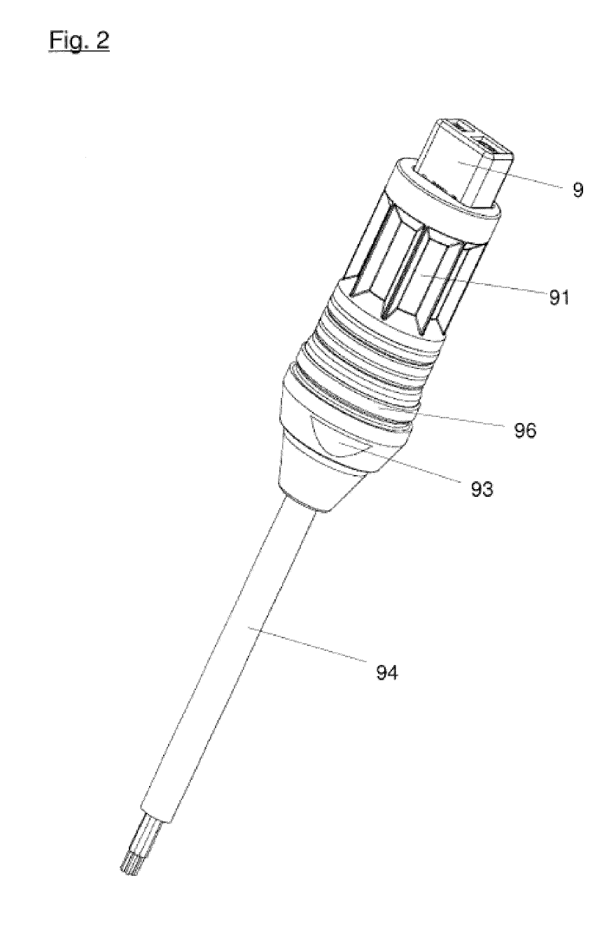

FIG. 2 shows a perspective illustration of the plug 9, with in this illustration the arrangement of the O-ring 96 at the front of the cap nut 93 for sealing the housing 6 is particularly clearly discernible.

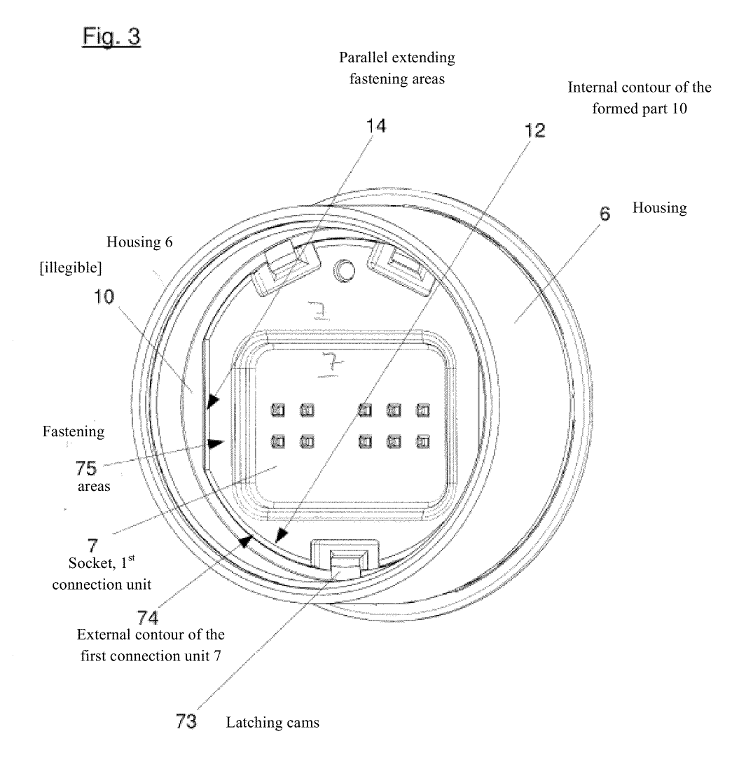

FIG. 3 shows a perspective illustration of the sensor unit 1 without the plug 9 being inserted, in a view diagonally from the rear.

In the view shown in FIG. 3 the support of the socket 7 in the formed part 10 is particularly clearly discernible. In the present exemplary embodiment, the formed part 10 is embodied with an essentially circular internal contour, with two parallel extending fastening sections 14 being provided radially opposite. The socket 7 comprises an external contour embodied corresponding to the internal contour 12 of the formed part 10, with here also parallel extending fastening sections 75 being provided radially opposite, which prevent any distortion of the socket 7 in reference to the formed part 10. In order to fixate the socket 7 in the axial direction it is here provided with latching cams 73 arranged at the external circumference. The latching cams 73 undercut the formed part 10 in the radial direction such that any axial motion of the socket 7 in reference to the formed part 10 is prevented. In the present exemplary embodiment three such latching cams 73 are provided at the socket 7, with different embodiments being possible too, for example two latching cams 73 arranged opposite.

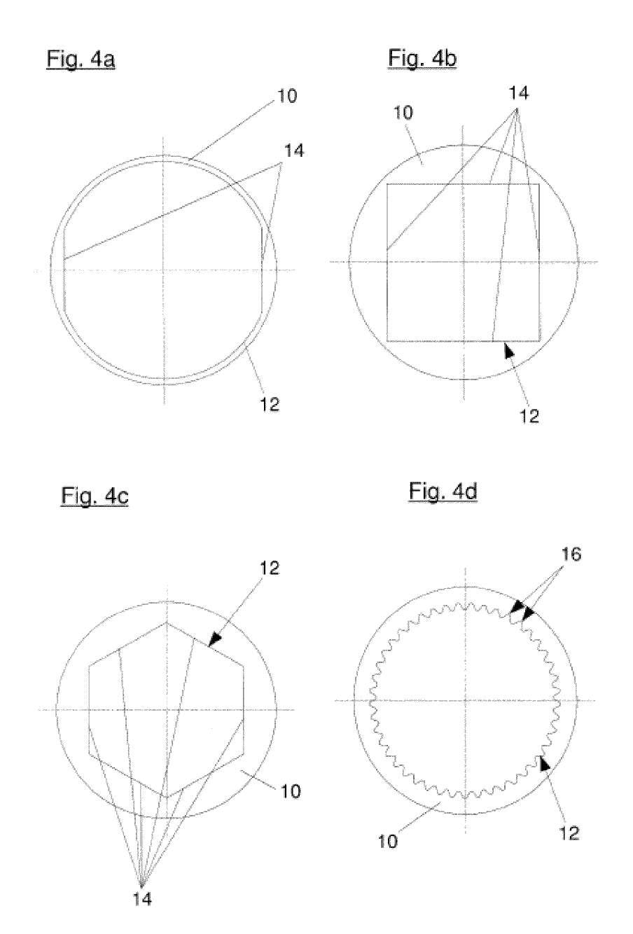

Various embodiments of a formed part 10 are shown In FIGS. 4a to 4d, which may be used in a sensor unit 1 as shown in FIG. 1.

FIG. 4a shows the formed part 10 of FIG. 3. As already explained, in this exemplary embodiment the formed part 10 comprises fastening areas 14, arranged opposite each other, which are aligned parallel and extend in the direction of a diameter at the perimeter of the formed part 10. The internal contour 12 of the formed part 10 is therefore essentially embodied circularly with two opposite area sections as the fastening sections 14.

FIG. 4b shows a second embodiment of a formed part 10, which may be used in a sensor unit 1 as shown for example in FIG. 1. In the embodiment shown the formed part 10 comprises an internal contour 12 with four fastening areas 14, thus the fastening areas 14 are arranged in a square fashion and form a square internal contour 12.

FIG. 4c shows a third embodiment of a formed part 10, with the internal contour 12 being embodied in the form of a regular hexagon, i.e. with six fastening areas 14 of identical length, with the fastening areas 14 being arranged opposite in pairs and extending parallel.

FIG. 4d shows a fourth exemplary embodiment of a formed part 10, with the internal contour 12 being embodied stellar with a plurality of recesses 16 extending radially outwardly. The internal contour 12 of the formed part 10 is therefore embodied essentially stellar and allows this way a plurality of different alignments of the socket (and) in reference to the formed part 10.

All of the above-mentioned formed parts 10, as shown in FIGS. 4a through 4d, in turn show circular external contours, and thus they can be processes for example via a machining process. The internal contour can be generated by a cutting process, for example.

For a particularly beneficial production of the formed parts 10 shown, depending on the material used, an injection molding, die casting, or metal injection molding process is used, though, or it is produced by cutting and machining. These production processes are well established in production technology and can yield respective formed parts in a process not requiring any extensive post-processing.

### LIST OF REFERENCE NUMBERS

1 Sensor unit
3 Sensor
5 Sensor electronic
6 Housing
7 First connection unit/socket
9 Second connection unit/plug
10 Formed part
12 Internal contour
14 Fastening area
16 Recess
71 Receptacle not marked in the illustrations
73 Latching cams
74 External contour
75 Fastening area
91 Plug housing
93 Cap nut
94 Connection cable
95 Strain relief
96 Seal

The references recited herein are incorporated herein in their entirety, particularly as they relate to teaching the level of ordinary skill in this art and for any disclosure necessary for the commoner understanding of the subject matter of the claimed invention. It will be clear to a person of ordinary skill in the art that the above embodiments may be altered or that insubstantial changes may be made without departing from the scope of the invention. Accordingly, the scope of the invention is determined by the scope of the following claims and their equitable Equivalents.

We claim:

1. A sensor unit comprising a sensor, a sensor electronic connected to the sensor, and a first connection unit, which is connected to the sensor electronic, with the sensor, the sensor electronic, and the first connection unit being arranged in a tubular housing, and with the second connection unit being able to contact a correspondingly embodied second connection unit, wherein a formed part with an internal contour is arranged in a torque-proof fashion in the housing, with the internal contour and an external contour of the first connection unit and/or the second connection unit being embodied sectionally in a mutually corresponding fashion, and the internal contour comprising at least one fastening section, which is embodied such that any distortion of the first and/or the second connection unit in reference to the formed part is prevented.

2. The sensor unit of claim 1, wherein the formed part is provided with an internal contour with at least two, preferably 4 or 6 fastening areas.

3. The sensor unit of claim 1, wherein the formed part is embodied with fastening areas arranged in pairs opposite each other and extending parallel.

4. The sensor unit of claim 1, wherein the formed part is embodied with a rectangle, regular hexagon, or a regular polygon as the internal contour.

5. The sensor unit of claim 1, wherein the internal contour comprises at least one recess pointing outwardly and the external contour at least one projection engaging the recess.

6. The sensor unit of claim 5, wherein the internal contour is embodied stellar.

7. The sensor unit of claim 1, wherein the formed part is impressed, adhered, welded, or soldered in the housing.

8. The sensor unit of claim 1, wherein the formed part is made from plastic, preferably in an injection molding process.

9. The sensor unit of claim 1, wherein the formed part is made from metal, preferably aluminum and preferably via a die casting process or from steel and preferably via a metal injection molding process.

10. The sensor unit of claim 1, wherein the formed part is produced via a metal injection molding process.

11. The sensor unit of claim 1, wherein the formed part is produced via a cutting process.

12. The sensor unit of claim 1, wherein the connection units establish an electric connection and the first connection unit is embodied as a socket and the second connection unit as a plug.

13. The sensor unit of claim 12, wherein the socket comprises latching elements, which undercut the formed part in a latching fashion for an axial fixation.

14. The sensor unit of claim 12, wherein the plug undercuts the socket and can be fastened via a cap nut at the housing.

15. The sensor unit of claim 1, wherein the internal contour is embodied such that an unambiguous assembly position of the connection unit is determined in reference to the formed part.
